(19) United States
(12) Patent Application Publication
(10) Pub. No.: US 2005/0258419 A1
(43) Pub. Date: Nov. 24, 2005

(54) System and method for making nanoparticles with controlled emission properties

(75) Inventors: R. Mohan Sankaran, Cleveland, OH (US); Konstantinos P. Giapis, Pasadena, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: California Institute of Technology, Pasadena, CA (US)

(21) Appl. No.: 11/123,885

(22) Filed: May 4, 2005

Related U.S. Application Data
(60) Provisional application No. 60/568,571, filed on May 5, 2004.

(51) Int. Cl. H01L 29/08; H01L 35/24

(52) U.S. Cl. 257/40

(57) ABSTRACT

A nanoparticle for emitting or absorbing light, and a system and method for making thereof. A nanoparticle for emitting or absorbing light includes a nanoparticle core including a core material and a nanoparticle surface passivated by at least a passivating material. The core material and the passivating material are different, and the nanoparticle is associated with a dimension equal to or less than 5 nm

### CROSS-REFERENCES TO RELATED APPLICATIONS

This application claims priority to U.S. Provisional No. 60/568,571 filed May 5, 2004, which is incorporated by reference herein.

The following two commonly-owned co-pending applications, including this one, are being filed concurrently and the other one is hereby incorporated by reference in its entirety for all purposes:
1. U.S. patent application Ser. No. ______, in the name of R. Mohan Sankaran, Konstantinos P. Giapis, Richard C. Flagan, and Dean Holunga, titled “System and Method for Making Nanoparticles Using Atmospheric-Pressure Plasma Microreactor” (Attorney Docket Number 020859-005010US); and
2. U.S. patent application Ser. No. ______, in the name of R. Mohan Sankaran and Konstantinos P. Giapis, titled “System and Method for Making Nanoparticles with Controlled Emission Properties” (Attorney Docket Number 020859-005110US).

### STATEMENT AS TO RIGHTS TO INVENTIONS MADE UNDER FEDERALLY SPONSORED RESEARCH OR DEVELOPMENT

Not Applicable

### REFERENCE TO A “SEQUENCE LISTING,” A TABLE, OR A COMPUTER PROGRAM LISTING APPENDIX SUBMITTED ON A COMPACT DISK

Not Applicable

### BACKGROUND OF THE INVENTION

The present invention relates generally to the field of nanotechnology. More specifically, the invention provides a method and system for making nanoparticles with controlled emission properties. Merely by way of example, the invention has been applied to modifying emission properties for silicon nanoparticles, but it would be recognized that the invention has a much broader range of applicability.

Materials synthesis for nanoparticles has attracted a great deal of interest because of unique electronic, magnetic, and optical properties at nanoscales. Reducing the size of semiconductor crystals, for example, leads to an increased optical band gap and size-dependent light emission which is desirable for applications in advanced optoelectronic devices. Silicon is of particular interest since it is the most important material in the semiconductor device industry. Although bulk Si, characterized by an indirect band gap, is not capable of emitting light efficiently, room temperature visible photoluminescence (PL) has been observed in porous Si and from nanoparticles with diameters less than 5 nm.

Silicon nanoparticles (np-Si) have been produced using a variety of techniques, such as colloidal growth, aerosol processes, plasma synthesis, and electrochemical etching. Within an aerosol flow reactor, the following processes occur at different time scales and locations. For example, initial nucleation of particles results from the formation of a supersaturated vapor of gas precursors. Possible means of generating a vapor source include pyrolysis, laser ablation, spark ablation, and plasmas. In the early stages, particles grow by condensation of vapor at their surface and coalescent coagulation. Normally, these processes occur in a region near the vapor source where the temperature is high. As the particle concentration increases, collisions between particles become more frequent and agglomeration begins. Formation of these undesirable aggregates is usually found away from the vapor source as the temperature drops off.

Hence the particles synthesized by the conventional aerosol processes often have a broad size distribution, which often necessitates post-synthesis size-selection and particle agglomeration. Notably, production of blue-light emitting np-Si has been challenging because of difficulties in limiting aerosol growth to small sizes and preventing particle coagulation. Furthermore, PL emission from Si nanoclusters has been theorized to occur through two main mechanisms including quantum confinement and surface-related processes. So controlling surface properties is also important for achieving desirable emission characteristics.

Hence it is desirable to improve techniques for making nanoparticles.

### BRIEF SUMMARY OF THE INVENTION

The present invention relates generally to the field of nanotechnology. More specifically, the invention provides a method and system for making nanoparticles with controlled emission properties. Merely by way of example, the invention has been applied to modifying emission properties for silicon nanoparticles, but it would be recognized that the invention has a much broader range of applicability.

According to an embodiment of the present invention, a nanoparticle for emitting or absorbing light includes a nanoparticle core including a core material and a nanoparticle surface passivated by at least a passivating material. The core material and the passivating material are different, and the nanoparticle is associated with a dimension equal to or less than 5 nm.

According to another embodiment of the present invention, a nanoparticle for emitting or absorbing light includes a nanoparticle core including silicon and a nanoparticle surface passivated by at least nitrogen. The nanoparticle is associated with a dimension equal to or less than 20 nm.

According to yet another embodiment of the present invention, a nanoparticle for emitting or absorbing light includes a nanoparticle core including silicon and a nanoparticle surface passivated by at least one selected from a group consisting of carbon and germanium. The nanoparticle is associated with a dimension equal to or less than 20 nm.

According to yet another embodiment of the present invention, a nanoparticle for emitting or absorbing light includes a nanoparticle core including germanium and a nanoparticle surface passivated by at least silicon. The nanoparticle is associated with a dimension equal to or less than 20 nm.

According to yet another embodiment of the present invention, a nanoparticle for emitting or absorbing light includes a nanoparticle core including silicon and a nanoparticle surface passivated by at least a metal material. The nanoparticle is associated with a dimension equal to or less than 20 nm.

According to yet another embodiment of the present invention, a nanoparticle for emitting or absorbing light includes a nanoparticle core including silicon and a nanoparticle surface passivated by at least a magnetic material. The nanoparticle is associated with a dimension equal to or less than 20 nm.

According to yet another embodiment of the present invention, a nanoparticle for emitting or absorbing light includes a nanoparticle core including a core material and a nanoparticle shell including a shell material and surrounding the nanoparticle core. The core material and the shell material are different, and the nanoparticle is associated with a dimension equal to or less than 5 nm.

According to yet another embodiment of the present invention, a nanoparticle for emitting or absorbing light includes a nanoparticle core including silicon and a nanoparticle shell surrounding the nanoparticle core. The nanoparticle shell includes nitrogen, and the nanoparticle is associated with a dimension equal to or less than 20 nm.

According to yet another embodiment of the present invention, a nanoparticle for emitting or absorbing light includes a nanoparticle core including silicon and a nanoparticle shell surrounding the nanoparticle core. The nanoparticle shell includes at least one selected from a group consisting of carbon and germanium, and the nanoparticle is associated with a dimension equal to or less than 20 nm.

According to yet another embodiment of the present invention, a nanoparticle for emitting or absorbing light includes a nanoparticle core including germanium and a nanoparticle shell surrounding the nanoparticle core. The nanoparticle shell includes silicon, and the nanoparticle is associated with a dimension equal to or less than 20 nm.

According to yet another embodiment of the present invention, a nanoparticle for emitting or absorbing light includes a nanoparticle core including silicon and a nanoparticle shell surrounding the nanoparticle core. The nanoparticle shell includes a metal material, and the nanoparticle is associated with a dimension equal to or less than 20 nm.

According to yet another embodiment of the present invention, a nanoparticle for emitting or absorbing light includes a nanoparticle core including silicon and a nanoparticle shell surrounding the nanoparticle core. The nanoparticle shell includes a magnetic material, and the nanoparticle is associated with a dimension equal to or less than 20 nm.

According to yet another embodiment of the present invention, a method for making nanoparticles with emission characteristics includes synthesizing a nanoparticle core including a core material and passivating a nanoparticle surface by at least a passivating material. The core material and the passivating material are different, and the nanoparticle core and the nanoparticle surface each are a part of a nanoparticle. The nanoparticle is associated with a dimension equal to or less than 5 nm.

According to yet another embodiment of the present invention, a method for making nanoparticles with emission characteristics includes synthesizing a nanoparticle core including silicon and passivating a nanoparticle surface by at least nitrogen. The nanoparticle core and the nanoparticle surface each are a part of a nanoparticle, and the nanoparticle is associated with a dimension equal to or less than 20 nm.

According to yet another embodiment of the present invention, a method for making a nanoparticle with emission characteristics includes synthesizing a nanoparticle core including silicon and passivating a nanoparticle surface by at least one selected from a group consisting of carbon and germanium. The nanoparticle core and the nanoparticle surface each are a part of a nanoparticle, and the nanoparticle is associated with a dimension equal to or less than 20 nm.

According to yet another embodiment of the present invention, a method for making a nanoparticle with emission characteristics includes synthesizing a nanoparticle core including germanium and passivating a nanoparticle surface by at least silicon. The nanoparticle core and the nanoparticle surface each are a part of a nanoparticle, and the nanoparticle is associated with a dimension equal to or less than 20 nm.

According to yet another embodiment of the present invention, a method for making nanoparticles with emission characteristics includes synthesizing a nanoparticle core including a core material and forming a nanoparticle shell including a shell material and surrounding the nanoparticle core. The core material and the shell material are different, and the nanoparticle core and the nanoparticle shell each are a part of a nanoparticle. The nanoparticle is associated with a dimension equal to or less than 5 nm.

According to yet another embodiment of the present invention, a method for making nanoparticles with emission characteristics includes synthesizing a nanoparticle core including silicon and forming a nanoparticle shell surrounding the nanoparticle core. The nanoparticle core and the nanoparticle shell each are a part of a nanoparticle, the nanoparticle shell includes nitrogen, and the nanoparticle is associated with a dimension equal to or less than 20 nm.

According to yet another embodiment of the present invention, a method for making nanoparticles with emission characteristics includes synthesizing a nanoparticle core including silicon and forming a nanoparticle shell surrounding the nanoparticle core. The nanoparticle core and the nanoparticle shell each are a part of a nanoparticle, the nanoparticle shell includes at least one selected from a group consisting of carbon and germanium, and the nanoparticle is associated with a dimension equal to or less than 20 nm.

According to yet another embodiment of the present invention, a method for making nanoparticles with emission characteristics includes synthesizing a nanoparticle core including germanium and forming a nanoparticle shell surrounding the nanoparticle core. The nanoparticle core and the nanoparticle shell each are a part of a nanoparticle, the nanoparticle shell includes silicon, and the nanoparticle is associated with a dimension equal to or less than 20 mm.

According to yet another embodiment of the present invention, a method for making nanoparticles with emission characteristics includes providing a plasma microreactor. The plasma microreactor includes a cathode associated with a first end and a second end, an anode associated with a third end and a fourth end, and a container including a gas inlet. The first end and the third end are separated by a gap and located inside the container. Additionally, the method includes supplying a first gas flowing from the second end to the first end, supplying a second gas flowing from the gas inlet into the anode through at least a part of the gap, and starting and maintaining a plasma discharge at a pressure equal to or higher than one atmospheric pressure. The first gas is used at least for synthesizing a nanoparticle core, and the second gas is used at least for passivating a nanoparticle surface surrounding the nanoparticle core. The nanoparticle core and the nanoparticle surface are each a part of a nanoparticle, and the nanoparticle is associated with a dimension equal to or less than 20 nm.

According to yet another embodiment of the present invention, a method for making nanoparticles with emission characteristics includes providing a plasma microreactor. The plasma microreactor includes a cathode associated with a first end and a second end, an anode associated with a third end and a fourth end, and a container including a gas inlet. The first end and the third end are separated by a gap and located inside the container. Additionally, the method includes supplying a first gas flowing from the second end to the first end, supplying a second gas flowing from the gas inlet into the anode through at least a part of the gap, and starting and maintaining a plasma discharge at a pressure equal to or higher than one atmospheric pressure. The first gas is used at least for synthesizing a nanoparticle core, and the second gas is used at least for forming a nanoparticle shell surrounding the nanoparticle core. The nanoparticle core and the nanoparticle shell each are a part of the nanoparticle, and the nanoparticle is associated with a dimension equal to or less than 20 nm.

According to yet another embodiment of the present invention, a system for making nanoparticles with emission characteristics includes a first cathode including a first metal tube associated with a first end and a second end, a first anode including a second metal tube associated with a third end and a fourth end, and a first container including a first gas inlet. The first end and the third end are located inside the first container. Additionally, the system includes a first furnace coupled to the fourth end associated with the first anode. The first end and the third end are separated by a first gap. The first metal tube is configured to allow a first gas to flow from the second end to the first end, and the first container is configured to allow a second gas to flow from the first gas inlet into the second metal tube through at least a part of the first gap. The first cathode and the first anode are configured to generate a first plasma discharge at a first pressure equal to or higher than one atmospheric pressure. The first plasma discharge is capable of being used for synthesizing at least a first nanoparticle core, and the first furnace is configured to passivate a first nanoparticle surface surrounding the first nanoparticle core. The first nanoparticle core and the first nanoparticle surface are each a part of a first nanoparticle, and the first nanoparticle is associated with a dimension equal to or less than 20 nm.

According to yet another embodiment of the present invention, a system for making nanoparticles with emission characteristics includes a first cathode including a first metal tube associated with a first end and a second end, a first anode including a second metal tube associated with a third end and a fourth end, and a first container including a first gas inlet. The first end and the third end are located inside the first container. Additionally, the system includes a first furnace coupled to the fourth end associated with the first anode. The first end and the third end are separated by a first gap. The first metal tube is configured to allow a first gas to flow from the second end to the first end, and the first container is configured to allow a second gas to flow from the first gas inlet into the second metal tube through at least a part of the first gap. The first cathode and the first anode are configured to generate a first plasma discharge at a first pressure equal to or higher than one atmospheric pressure. The first plasma discharge is capable of being used for synthesizing at least a first nanoparticle core, and the first furnace is configured to passivate a first nanoparticle shell surrounding the first nanoparticle core. The first nanoparticle core and the first nanoparticle shell each are a part of a first nanoparticle, and the first nanoparticle is associated with a dimension equal to or less than 20 nm.

According to yet another embodiment of the present invention, a nanoparticle for emitting or absorbing light includes a nanoparticle core including silicon and a nanoparticle surface passivated by at least oxygen. The nanoparticle is associated with a dimension equal to or less than 5 nm.

According to yet another embodiment of the present invention, a nanoparticle for emitting or absorbing light includes a nanoparticle core including silicon and a nanoparticle shell surrounding the nanoparticle core. The nanoparticle shell includes oxygen, and the nanoparticle is associated with a dimension equal to or less than 5 nm.

According to yet another embodiment of the present invention, a method for making nanoparticles with emission characteristics includes synthesizing a nanoparticle core including silicon and passivating a nanoparticle surface by at least oxygen. The nanoparticle core and the nanoparticle surface each are a part of a nanoparticle, and the nanoparticle is associated with a dimension equal to or less than 5 nm.

According to yet another embodiment of the present invention, a method for making nanoparticles with emission characteristics includes synthesizing a nanoparticle core including silicon and forming a nanoparticle shell surrounding the nanoparticle core. The nanoparticle core and the nanoparticle shell each are a part of a nanoparticle, and the nanoparticle shell includes oxygen. The nanoparticle is associated with a dimension equal to or less than 5 nm.

Many benefits are achieved by way of the present invention over conventional techniques. For example, some embodiments of the present invention provide high-pressure microdischarges for the synthesis of nanometer-size particles with controlled emission properties. For example, the emission properties of the silicon nanoparticles are tailored to range from 350 to 700 nm. Certain embodiments of the present invention modify surface characteristics of nanoparticles. Some embodiments of the present invention can be applied to imaging and/or energy conversion. Certain embodiments of the present invention can be used for solar cells, LEDs, photodiodes, diode lasers, and/or memory systems.

Depending upon embodiment, one or more of these benefits may be achieved. These benefits and various additional objects, features and advantages of the present invention can be fully appreciated with reference to the detailed description and accompanying drawings that follow.

### BRIEF DESCRIPTION OF THE DRAWINGS

FIG. 1 is a simplified method for making nanoparticles with controlled emission characteristics according to an embodiment of the present invention;

FIGS. 2(A) and 2(B) each show a simplified system for making nanoparticles with controlled emission characteristics according to an embodiment of the present invention;

FIG. 3 is a simplified method for making silicon nanoparticles according to an embodiment of the present invention;

FIG. 4 shows simplified size distributions fitted with D_{g} and σ_{g} according to an embodiment of the present invention;

FIG. 5 shows simplified PL spectra from suspended silicon nanoparticles according to an embodiment of the present invention;

FIG. 6 shows simplified PL spectra from suspended silicon nanoparticles according to another embodiment of the present invention;

FIG. 7 shows simplified PL spectra from suspended silicon nanoparticles according to yet another embodiment of the present invention;

FIG. 8 shows simplified comparison of PL spectra according to an embodiment of the present invention;

FIG. 9 is a simplified diagram showing photoemission as a function of oxygen concentration according to an embodiment of the present invention.

### DETAILED DESCRIPTION OF THE INVENTION

The present invention relates generally to the field of nanotechnology. More specifically, the invention provides a method and system for making nanoparticles with controlled emission properties. Merely by way of example, the invention has been applied to modifying emission properties for silicon nanoparticles, but it would be recognized that the invention has a much broader range of applicability.

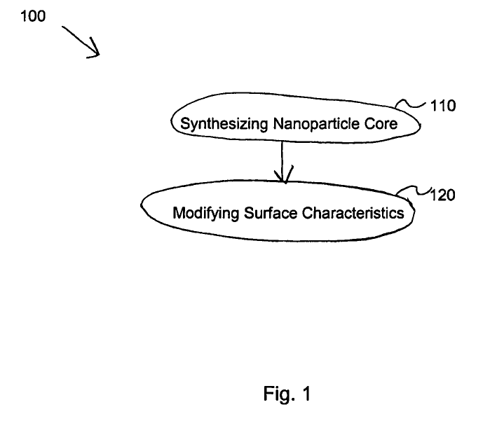

FIG. 1 is a simplified method for making nanoparticles with controlled emission characteristics according to an embodiment of the present invention. This diagram is merely an example, which should not unduly limit the scope of the claims. One of ordinary skill in the art would recognize many variations, alternatives, and modifications. The method 100 includes a process 110 for synthesizing nanoparticle core and a process 120 for modifying surface characteristics. Although the above has been shown using a selected sequence of processes, there can be many alternatives, modifications, and variations. For example, some of the processes may be expanded and/or combined. Other processes may be inserted to those noted above. Depending upon the embodiment, the specific sequence of processes may be interchanged with others replaced. For example, the processes 110 and 120 are performed sequentially. In another example, the processes 110 and 120 partially or completely overlap in time. Further details of these processes are found throughout the present specification and more particularly below.

At the process 110, a nanoparticle core including a core material is synthesized. In one embodiment, the nanoparticle core includes a semiconductor material. For example, the core includes silicon, germanium, or mixture of silicon and germanium. In another embodiment, the core includes a metal material. For example, the metal material includes iron, cobalt, and/or nickel. In yet another embodiment, the core includes a magnetic material.

The nanoparticle core has a dimension, e.g., a diameter. For example, the core dimension is less than 100 nm. In another example, the core dimension is less than 20 nm. In yet another example, the core dimension is equal to or less than 5 nm. In yet another example, the core dimension is equal to or less than 3 nm.

At the process 120, surface characteristics of the nanoparticle core is modified. In one embodiment, the core surface is passivated by a passivating material. For example, the passivating material is different from the core material. In another example, the passivation reduces or eliminates the dangling bonds of the nanoparticle core. In yet another example, the passivating material includes nitrogen, oxygen, carbon, germanium, and/or silicon. In yet another example, the passivating material includes a metal material, such as Fe, Ni., and Co. In yet another example, the core material includes silicon, and the passivation forms chemical bonds between silicon atoms and nitrogen atoms, silicon atoms and oxygen atoms, silicon atoms and carbon atoms, silicon atoms and germanium atoms, and/or silicon atoms and metal atoms.

In another embodiment, the core surface is covered by an outer layer. For example, the outer layer is a nanoparticle shell surrounding the nanoparticle core. In another example, the nanoparticle shell includes a shell material. In yet another example, the shell material is different from the core material. In yet another example, the outer layer includes nitrogen, oxygen, carbon, and/or germanium. In yet another example, the nanoparticle core includes silicon and/or germanium, and the outer layer includes a metal material, such as Fe, Ni., and Co. In yet another example, the nanoparticle core includes silicon and/or germanium, and the outer layer includes a magnetic material.

The nanoparticle has a dimension, e.g., a diameter. For example, the nanoparticle dimension is less than 100 nm. In another example, the nanoparticle dimension is less than 20 nm. In yet another example, the nanoparticle dimension is equal to or less than 5 nm. In yet another example, the nanoparticle dimension is equal to or less than 3 nm.

In yet another embodiment, the nanoparticles have a dimension, e.g., a diameter, of a mean value ranging from 1 to 2 nm. For example, the silicon nanoparticles with nitrogen as the gas 324 has a mean diameter of 1.6 nm with a standard deviation of 0.4 nm. In another example, the silicon nanoparticles with argon and oxygen as the gas 324 each have a nanoparticle core that has a diameter with a mean value of 1.6 nm and a standard deviation of 0.4 nm. In yet another example, the size measurements are performed by atomic force microscopy and/or photoluminescence.

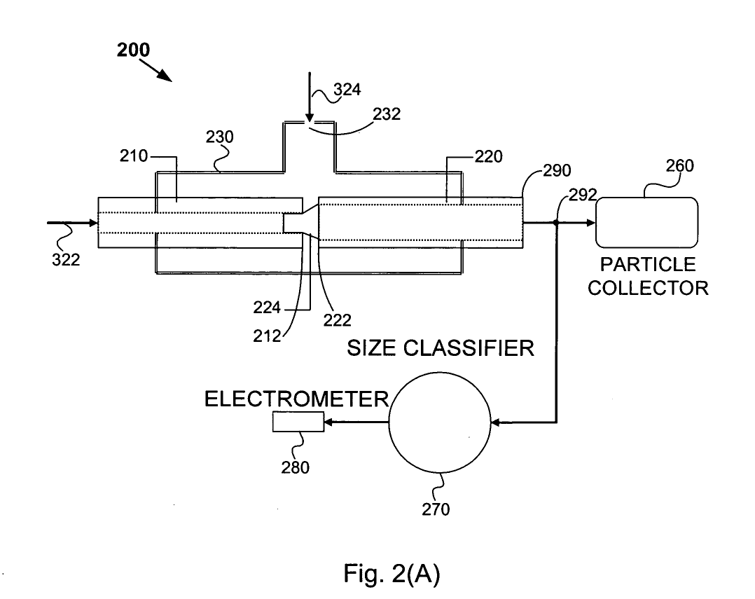

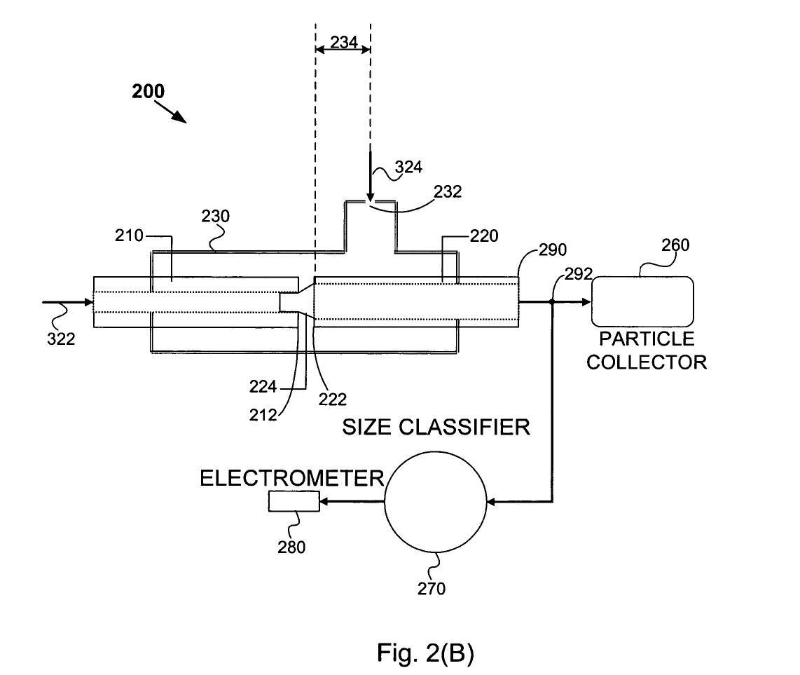

FIGS. 2(A) and 2(B) each show a simplified system for making nanoparticles with controlled emission characteristics according to an embodiment of the present invention. These diagrams are merely examples, which should not unduly limit the scope of the claims. One of ordinary skill in the art would recognize many variations, alternatives, and modifications. A system 200 includes a cathode 210, an anode 220, a sealing tube 230, particle collector 260, a size classifier 270, and an electrometer 280. Although the above has been shown using a selected group of components for the system 200, there can be many alternatives, modifications, and variations. For example, some of the components may be expanded and/or combined. Other components may be inserted to those noted above. Depending upon the embodiment, the arrangement of components may be interchanged with others replaced. For example, the size classifier 270 and the electrometer 280 are removed. Further details of these components are found throughout the present specification and more particularly below.

The cathode 210 is made of a metal tube. For example, the metal tube includes a stainless steel capillary tube. The metal tube has an outer diameter and an inner diameter. For example, the inner diameter ranges from 10 μm to 250 μm. In another example, the inner diameter equals about 180 μm. The cathode 210 is connected a voltage source. For example, the cathode 210 is biased to the ground level.

The anode 220 is made of a metal tube. The metal tube has an outer diameter and an inner diameter. For example, the inner diameter ranges from 250 μm to 2.0 mm. In another example, the inner diameter ranges from 0.5 mm to 2.0 mm. In yet another example, the inner diameter equals about 1 mm. The cathode 220 is connected to a voltage source. For example, the cathode 210 is biased to a voltage level ranging from 0 volts to 2000 volts. In other embodiments, the anode 220 is made of a screen, a ring, a point, and/or a substrate.

In one embodiment, the inner diameter of the anode 220 is larger than the inner diameter of the cathode 210. For example, the inner diameter of the anode 220 is at least twice as large as the inner diameter of the cathode 220. In another example, the inner diameter of the anode 220 is at least three times as large as the inner diameter of the cathode 220. In another embodiment, the anode 220 is shorter than the cathode 210. For example, this arrangement reduces particle loss to the walls of the metal tube for the anode 220.

As shown in FIGS. 2(A) and 2(B), the cathode 210 has an end 212, and the anode 220 has an end 222. The two ends 212 and 222 are separated by a gap 224. For example, the gap 224 has a length ranging from 0.5 to 2 mm. In another example, the length of the gap 224 is equal to about 1 mm. In yet another example, the length of the gap 224 can be adjusted using a micrometer. At least part of the cathode 210 and at least part of the anode 220 are pressure sealed in the sealing tube 230. For example, the sealing tube 230 is a Pyrex glass tube or a quartz tube.

The sealing tube 230 has an gas inlet 232. The gas inlet 232 can be placed at various locations. For example, as shown in FIG. 2(A), the gas inlet 232 is located next to the gap 212 instead of on either the anode side or the cathode side. In another example, as shown in FIG. 2(B), the gas inlet 232 is located on the anode side. Along the anode direction, the gas inlet 232 is away from the end 222 by a distance 234. For example, the distance 234 ranges from 2 to 4 mm.

The particle collector 260 is used to collect silicon nanoparticles. In one embodiment, the particle collector 260 includes liquid for collection. For example, dispersions of particles are obtained in solution by bubbling the aerosol stream through a glass frit into an organic solvent, which has been out-gassed for 1 to 2 hours to remove dissolved oxygen. In another example, 1-octanol is used as the organic solvent to stabilize silicon particles. After collecting particles for 24 hours, the solvent is removed by vacuum evaporation and the particles are re-dispersed in hexane. In another embodiment, the particle collector 260 includes a substrate used for collection. As an example, films of particles are deposited on a molybdenum substrate in stagnation flow downstream from the discharge.

The size classifier 270 includes a radial differential mobility analyzer (RDMA) which can detect charged particles. The RDMA is often preceded by a bipolar charger, such as a sealed ⁸⁵Kr β-source, to ensure proper charging of the particles. The inventors of the instant application discovered that the bipolar charger enhances particle coagulation thus shifting the distribution to larger sizes. In one embodiment of the present invention, the bipolar charger is not used. Instead, the silicon nanoparticles are directed straight into the RDMA, which could then measure distributions of particles charged by a plasma. The electrometer 280 is coupled to the size classifier 270. For example, the electrometer 280 is Keithley Model 6514.

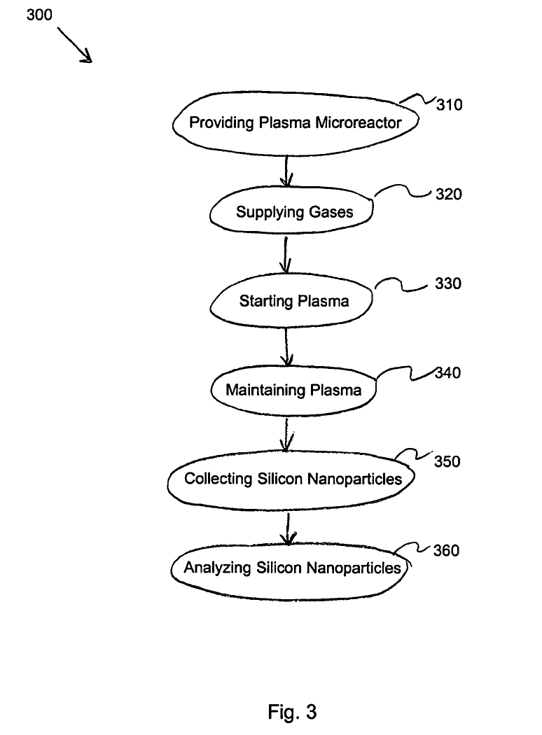

FIG. 3 is a simplified method for making silicon nanoparticles according to an embodiment of the present invention. This diagram is merely an example, which should not unduly limit the scope of the claims. One of ordinary skill in the art would recognize many variations, alternatives, and modifications. The method 300 includes a process 310 for providing plasma microreactor, a process 320 for supplying gases, a process 330 for starting plasma, a process 340 for maintaining plasma, a process 350 for collecting silicon nanoparticles, and a process 360 for analyzing silicon nanoparticles. Although the above has been shown using a selected sequence of processes, there can be many alternatives, modifications, and variations. For example, some of the processes may be expanded and/or combined. Other processes may be inserted to those noted above. In one embodiment, the method 300 is an example of the method 100. Depending upon the embodiment, the specific sequence of processes may be interchanged with others replaced. For example, the process 360 is skipped. In another example, the method 300 is used to make nanoparticles other than silicon nanoparticles. In one embodiment, the synthesized nanoparticles have nanoparticle cores that include a core material other than silicon. In another embodiment, the synthesized nanoparticles are different from silicon nanoparticles, and they are collected and/or analyzed. Further details of these processes are found throughout the present specification and more particularly below.

At the process 310, a plasma microreactor is provided. For example, the plasma microreactor includes the system 200. At the process 320, certain gases are supplied to the plasma microreactor. For example, a gas mixture 322 flows through the cathode 210. The gas mixture 322 includes a gas precursor and an inert gas for diluting the gas precursor. In one embodiment, the gas precursor is silane, and the inert gas is argon. For example, the silane concentration within the gap 224 is controlled between 1 to 5 ppm by varying the flow rate of a 50-ppm SiH₄/Ar mixture while maintaining a constant total flow rate with a balance of argon.

Additionally, a gas 324 flows through the gas inlet 232 to regions outside of the cathode 210 within the system 200. For example, the gas 324 has a flow rate approximately three times larger than the gas mixture 322. In one embodiment, the gas 324 includes argon. For example, an argon gas with 99.9995% purity is run through a copper getter gas purifier heated to 350° C. to completely remove oxygen before flowing into the plasma microreactor 200. In another embodiment, the gas 324 includes nitrogen. In yet another embodiment, the gas 324 includes oxygen.

At the process 330, a plasma discharge is started. For example, the discharge exists in the hollow cathode 210 and extends towards the anode 220. In one embodiment, the discharge is formed by applying a voltage to the anode 220 while keeping the potential of the cathode 210 at the ground level. For example, the voltage ranges from 1000 to 2000 volts. In another embodiment, the discharge is formed by reducing the length of the gap 212, and applying a voltage to a voltage to the anode 220 while keeping the potential of the cathode 210 at the ground level. For example, the voltage is lower than 1000 volts. In another example, the plasma discharge is started at a pressure equal to or higher than one atmospheric pressure.

At the process 340, the plasma discharge is maintained. In one embodiment, the length of the gap 224 ranges from 0.5 to 2 mm. For example, the voltage for sustaining the discharge ranges from 300 to 500 volts. In another example, the current ranges from 3 to 10 mA. In another embodiment, the plasma discharge is maintained at a pressure equal to or higher than one atmospheric pressure.

In yet another embodiment, the process 340 includes making nanoparticles with controlled emission characteristics. For example, silicon nanoparticles are formed within the plasma discharge. Surface characteristics of silicon nanoparticles are controlled and/or modified by the gas 324. For example, surfaces of silicon nanoparticles are passivated by the gas 324. In anther example, the silicon nanoparticles each include an outer layer and a core.

At the process 350, the nanoparticles are collected. For example, silicon nanoparticles are collected in liquid and/or on a substrate. In another example, silicon nanoparticles are collected by the particle collector 260.

As discussed above, at the processes 330 and 340, the plasma discharge is started and maintained. For example, the discharge exists in the hollow cathode 210 and extends towards the anode 220. In one embodiment, the plasma density is higher in part of the hollow cathode 210 than in the gap 224. In another embodiment, nanoparticle cores are mostly synthesized in the hollow cathode 210. At the gap 224, the gas 324 starts passivating surfaces of nanoparticle cores, and/or forming outer layers on nanoparticle cores. These processes can continue in the hollow anode 220. Additionally, at the gap 224, the gas 324 starts quenching the nanoparticles, and the quenching continues in the hollow anode 220.

At the process 360, the nanoparticles are analyzed. For example, the process 360 is performed before and/or after the process 350. In one embodiment, the sizes of the nanoparticles are measured by the size classifier 270 and the electrometer 280.

As discussed above and further emphasized here, the method 300 can be used to make nanoparticles with the system 200 according to one embodiment of the present invention. For example, the nanoparticles emit and/or absorb light in response to irradiation of photons and/or irradiation of charged particles. In another example, the nanoparticles emit and/or absorb light in response to electric current.

In one embodiment, the nanoparticles emit light in response to illumination. For example, the illumination wavelength is different from the emission wavelength. In another example, the illumination wavelength is the same as the emission wavelength. In yet another embodiment, the illumination corresponds to multiple wavelengths, and/or the emission corresponds to multiple wavelengths.

For example, silicon nanoparticles are synthesized with the gas 322 including silane. In another example, metal nanoparticles are synthesized with the gas 322 including metal carbonyls. In one embodiment, nickel nanoparticles are made with the gas 322 including Ni(CO)₆. In another embodiment, metal nanoparticles are iron, cobalt, and/or nickel nanoparticles. In yet another example, iron nanoparticles are made with the gas 322 including ferrocene (Fe(C₅H₅)₂). In yet another example, germanium nanoparticles are made with the gas including Germane (GeH₄).

In yet another embodiment, multiple systems 200 are used in parallel to make nanoparticles according to the method 300. In another embodiment, the system 200 produces a direct-current (dc), atmospheric-pressure microdischarge for particle synthesis. In yet another embodiment, the system 200 uses the inert gas 324 to reduce coagulation of the nanoparticles downstream of the plasma reaction zone.

In one embodiment, as shown in FIG. 2(B), the inert gas 324 flows through the gas inlet 232. In one embodiment, the gas inlet 232 is located on the anode side instead of on the cathode side. The inventors of the present invention have discovered that such arrangement provides certain advantages over placing the gas inlet 232 next to the gap 224 or on the cathode side. For example, placing the gas inlet 232 on the cathode side can lower the temperature of the cathode and thus produce undesirable effects. In another example, placing the gas inlet 232 on the anode side can improve uniformity of the gas 324 flowing into the anode.

According to yet another embodiment, silicon nanoparticles are made with the system 200 according to the method 300. For example, the gas mixture 322 includes silane and argon. The synthesized silicon nanoparticles are characterized by the size classifier 270 and the electrometer 280. For example, the size classifier 270 includes a radial differential mobility analyzer (RDMA).

In RDMA, the orientation of the electric field for size measurements is such that positively charged particles are transmitted. In the range of silane concentrations explored here, the discharge is stable with highly reproducible size distributions. Fitting to the following log-normal distribution provides estimates of the geometrical mean diameter (D_{g}) and geometrical standard deviation (σ_{g}):

$$\frac{ⅆ N}{ⅆ ln {D}_{p}} = \frac{N}{{( 2 π )}^{1 / 2} ln {σ}_{g}} exp ( - \frac{{( ln {D}_{p} - ln {D}_{g} )}^{2}}{2 {ln}^{2} {σ}_{g}} ) \qquad ( Equation 1 )$$

where N is the total aerosol number concentration, and D_{P} is the mean diameter. Regression to the log-normal distribution has been performed with D_{g} and σ_{g} as the fitting parameters.

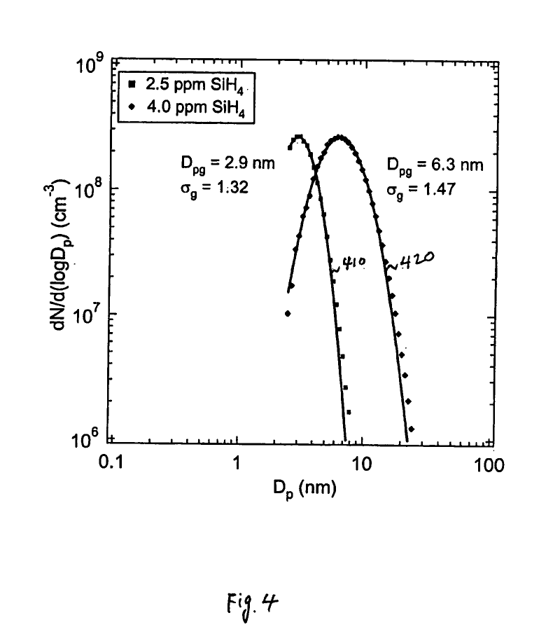

FIG. 4 shows simplified size distributions fitted with D_{g} and σ_{g} according to an embodiment of the present invention. This diagram is merely an example, which should not unduly limit the scope of the claims. One of ordinary skill in the art would recognize many variations, alternatives, and modifications. The silicon nanoparticles are synthesized by the method 300 with the system 200. For example, the total flow rate of the gas 322 is about 150 sccm, and the gas 324 has a flow rate of about 450 sccm. The electrode gap 224 is about 1-mm long, and the discharge current is about 6 mA. A curve 410 represents a size distribution for a silane concentration of 2.5 ppm, and a curve 820 represents a size distribution for a silane concentration of 4.0 sccm. Both curves are closely approximated by the log-normal fit, but exhibit a tail at larger diameters. At a silane concentration of 2.5 ppm, D_{g} and σ_{g} have been found to be 2.9 nm and 1.32, respectively. The observed σ_{g} compares favorably with values measured by other growth processes without size-selection which were reported to be between 1.5 to 1.6. Increasing the silane concentration to 4.0 ppm increases D_{g} and σ_{g} to 6.2 nm and 1.45, respectively. The increasing value of σ_{g} at higher silane concentrations may indicate the onset of particle growth by agglomeration.

According to an embodiment of the present invention, PL measurements have been performed at room temperature on hexane-suspended np-Si, and excitation and emission spectra have been obtained using a spectrophotometer. For example, the spectrophotometer is Model QM by Photon Technology International.

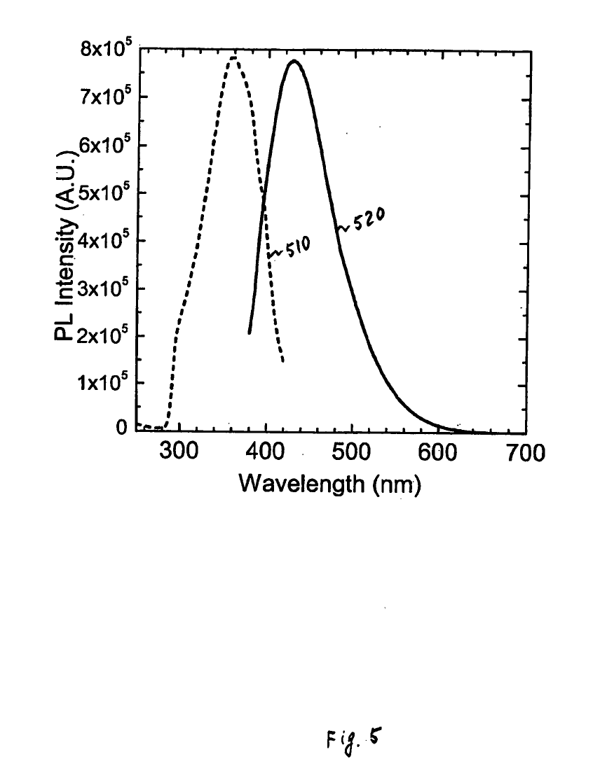

FIG. 5 shows simplified PL spectra from suspended silicon nanoparticles according to an embodiment of the present invention. This diagram is merely an example, which should not unduly limit the scope of the claims. One of ordinary skill in the art would recognize many variations, alternatives, and modifications. The silicon nanoparticles are synthesized by the method 300 with the system 200. For example, the flow rate of silane is about 2.5 ppm, and the gas 324 is argon. A curve 510 represents a room-temperature PL excitation spectrum collected by fixing the detection at 420 nm, and a curve 520 represents a room-temperature PL emission spectrum with fixed excitation wavelength at 360 nm. These curves have been taken for silicon nanoparticles in hexane solution. As shown in FIG. 5, the spectra 510 and 520 exhibit an excitation peak at 360 nm and an emission maximum at 420 nm. The strong blue emission is readily observable by naked eye. The band gap for silicon nanoparticles, for example, equals about 2.8 or 2.9 eV.

Assuming that the PL emission at 420 nm or 2.95 eV is excitonic, the silicon particle core size can be estimated from calculations to be less than 2 nm. This size is significantly smaller than the RDMA measurement. The size discrepancy could be related to smaller particle agglomeration in the aerosol measurements or larger particle oxidation upon exposure to ambient air. Particles grown at higher silane concentrations, which appear to be bigger according to the RDMA, do not exhibit red-shifted PL peaks as expected from quantum confinement. Hence the short residence time in the microreactor may have limited the primary particle size in the 1-2 nm range. Larger silane concentrations result in the production of more particles in the same size range.

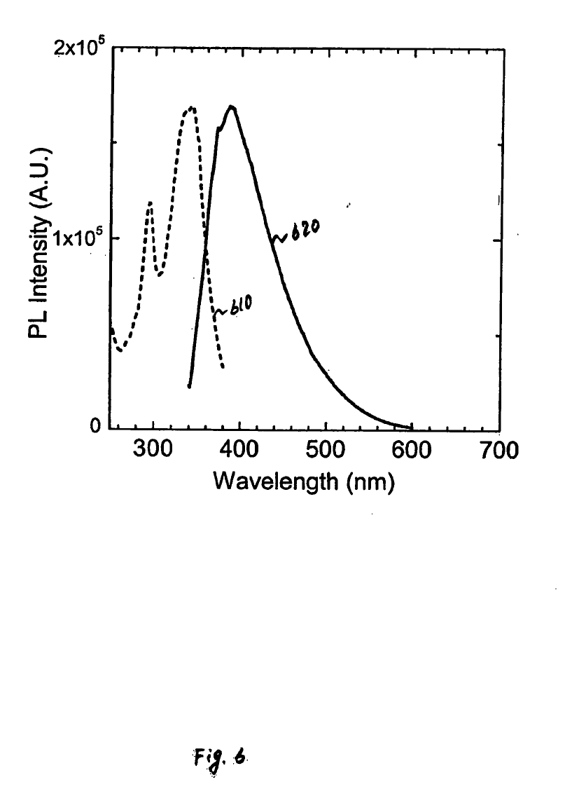

FIG. 6 shows simplified PL spectra from suspended silicon nanoparticles according to another embodiment of the present invention. This diagram is merely an example, which should not unduly limit the scope of the claims. One of ordinary skill in the art would recognize many variations, alternatives, and modifications. The silicon nanoparticles are synthesized by the method 300 with the system 200. For example, the flow rate of silane is about 2.5 ppm, and the gas 324 is nitrogen. A curve 610 represents a room-temperature PL excitation spectrum collected by fixing the detection at 390 nm, and a curve 620 represents a room-temperature PL emission spectrum with fixed excitation wavelength at 340 nm. These curves have been taken for silicon nanoparticles in hexane solution. As shown in FIG. 6, the spectra 610 and 620 exhibit an excitation peak at 340 nm and an emission maximum at 390 nm.

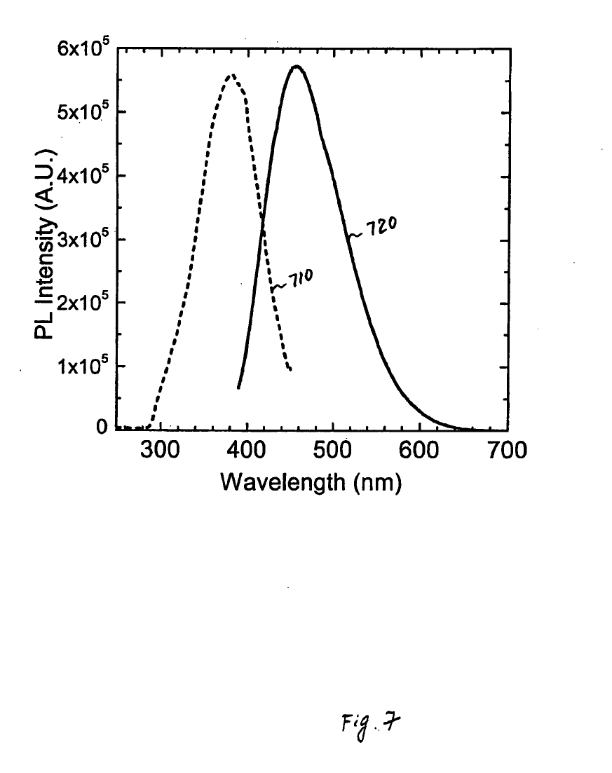

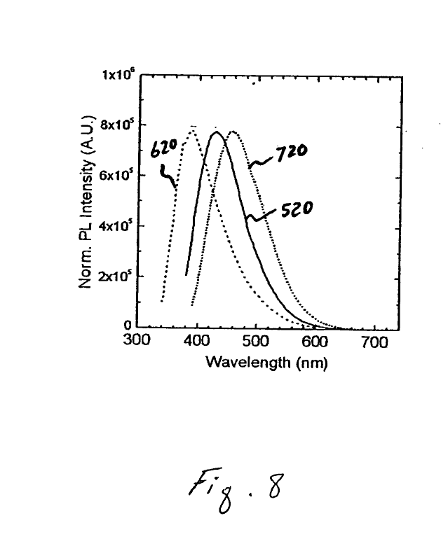

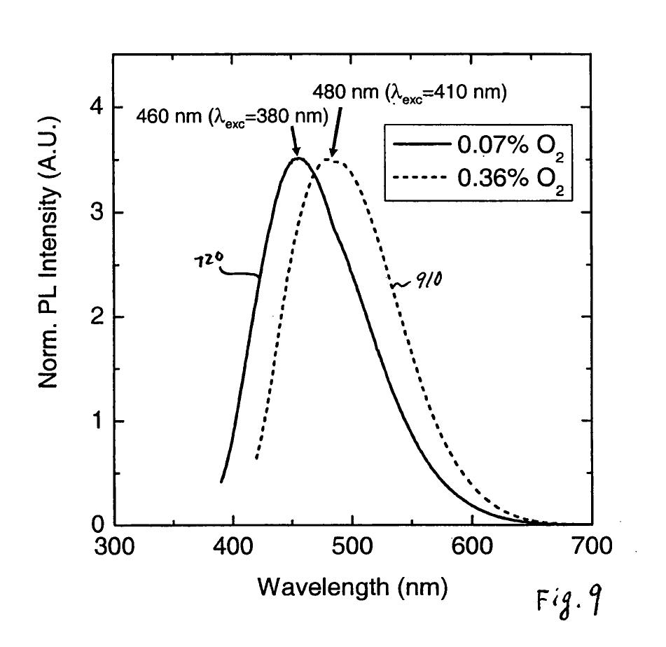

FIG. 7 shows simplified PL spectra from suspended silicon nanoparticles according to yet another embodiment of the present invention. This diagram is merely an example, which should not unduly limit the scope of the claims. One of ordinary skill in the art would recognize many variations, alternatives, and modifications. The silicon nanoparticles are synthesized by the method 300 with the system 200. For example, the flow rate of silane is about 2.5 ppm, and the gas 324 includes 0.07% of oxygen and 99.93% of argon in volume. A curve 710 represents a room-temperature PL excitation spectrum collected by fixing the detection at 460 nm, and a curve 720 represents a room-temperature PL emission spectrum with fixed excitation wavelength at 380 nm. These curves have been taken for silicon nanoparticles in hexane solution. As shown in FIG. 7, the spectra 710 and 720 exhibit an excitation peak at 380 nm and an emission maximum at 460 nm. The strong green emission is readily observable by naked eye.

FIG. 8 shows simplified comparison of PL spectra according to an embodiment of the present invention. This diagram is merely an example, which should not unduly limit the scope of the claims. One of ordinary skill in the art would recognize many variations, alternatives, and modifications. As shown in FIG. 8, the curve 620 corresponds to the use of nitrogen as the gas 324, the curve 520 corresponds to the use of argon as the gas 324, and the curve 620 corresponds to the use of oxygen and argon as the gas 324. By altering the composition of the gas 324, the photoemission wavelength of the silicon nanoparticles is shifted. For example, replacing argon with nitrogen, the excitation and emission spectra are blue-shifted to smaller wavelength. In another example, replacing argon with a mixture of argon and oxygen, the excitation and emission spectra are red-shifted to larger wavelength.

FIG. 9 is a simplified diagram showing photoemission as a function of oxygen concentration according to an embodiment of the present invention. This diagram is merely an example, which should not unduly limit the scope of the claims. One of ordinary skill in the art would recognize many variations, alternatives, and modifications. Curves 720 and 910 are room-temperature PL emission spectra for silicon nanoparticles with fixed excitation wavelength at 380 nm and 410 nm respectively. The silicon nanoparticles are synthesized by the method 300 with the system 200. For the curve 720, the flow rate of silane is about 2.5 ppm, and the gas 324 includes 0.07% of oxygen and 99.3% of argon in volume. For the curve 910, the flow rate of silane is about 2.5 ppm, and the gas 324 includes 0.36% of oxygen and 99.64% of argon in volume. As shown in FIG. 9, by altering oxygen concentration for the gas 324, the maximum photoemission of silicon nanoparticles are shifted from 460 nm to 480 nm.

As discussed above and further emphasized here, FIGS. 1-9 are merely examples, which should not unduly limit the scope of the claims. One of ordinary skill in the art would recognize many variations, alternatives, and modifications. For example, in FIGS. 5-8, curves 510, 520, 610, 620, 710, 720, and 910 each represent intensity counts or normalized intensities as a function of wavelength. In another example, the process 120 can be used to control photoluminescence lifetime of the nanoparticles by modifying surface characteristics of the nanoparticle core. In yet another example, the process 120 can be used to reduce or eliminate blinking of the nanoparticles. Without surface modification, the nanoparticles often exhibit intermittence in emission under continuous illumination. Such intermittence can reduce brightness of ensemble emission. Hence reduction of blinking is important for certain applications.

In another embodiment, the system 200 in FIGS. 2(A) and 2(B) is modified. For example, a furnace is inserted between an end 290 of the anode 220 and the node 292. In another example, the size classifier 270 and the electrometer 280 are removed. The furnace is inserted between the end 290 and the particle collector 260. According to one embodiment, the furnace is provided with a gas and used to modify the surface characteristics of the nanoparticle core. For example, prior to entering the furnace, the nanoparticle core includes at least one shell layer. In another example, prior to entering the furnace, the nanoparticle core does not include any shell layer. In one embodiment, the nanoparticle surface is passivated at the furnace. In another embodiment, a nanoparticle shell is formed surrounding the nanoparticle core at the furnace. In yet another embodiment, the process 120 is performed with the gas 324 and/or the gas provided to the furnace.

In yet another embodiment, the system 200 in FIGS. 2(A) and 2(B) is modified. For example, the nanoparticles formed by a first plasma discharge flow to a second plasma discharge prior to being collected. According to one embodiment, the second plasma discharge is provided with a gas and used to modify the surface characteristics of the nanoparticle core. For example, prior to entering the second plasma discharge, the nanoparticle core includes at least one shell layer. In another example, prior to entering the second plasma discharge, the nanoparticle core does not include any shell layer. In one embodiment, the nanoparticle surface is passivated at the second plasma discharge. In another embodiment, a nanoparticle shell is formed surrounding the nanoparticle core at the second plasma discharge. In yet another embodiment, the process 120 is performed with the gas 324 and/or the gas provided to the second plasma discharge.

According to an embodiment of the present invention, a nanoparticle for emitting or absorbing light includes a nanoparticle core including a core material and a nanoparticle surface passivated by at least a passivating material. The core material and the passivating material are different, and the nanoparticle is associated with a dimension equal to or less than 5 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle surface passivated by at least nitrogen. The nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle surface passivated by at least one selected from a group consisting of carbon and germanium. The nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including germanium and a nanoparticle surface passivated by at least silicon. The nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle surface passivated by at least a metal material. The nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle surface passivated by at least a magnetic material. The nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including a core material and a nanoparticle shell including a shell material and surrounding the nanoparticle core. The core material and the shell material are different, and the nanoparticle is associated with a dimension equal to or less than 5 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle shell surrounding the nanoparticle core. The nanoparticle shell includes nitrogen, and the nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle shell surrounding the nanoparticle core. The nanoparticle shell includes at least one selected from a group consisting of carbon and germanium, and the nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including germanium and a nanoparticle shell surrounding the nanoparticle core. The nanoparticle shell includes silicon, and the nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle shell surrounding the nanoparticle core. The nanoparticle shell includes a metal material, and the nanoparticle is associated with a dimension equal to or less than 20 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle shell surrounding the nanoparticle core. The nanoparticle shell includes a magnetic material, and the nanoparticle is associated with a dimension equal to or less than 20 nm. For example, the nanoparticle is made according to the method 100 and/or the method 300 with the system 200.

According to yet another embodiment of the present invention, a method for making nanoparticles with emission characteristics includes synthesizing a nanoparticle core including a core material and passivating a nanoparticle surface by at least a passivating material. The core material and the passivating material are different, and the nanoparticle core and the nanoparticle surface each are a part of a nanoparticle. The nanoparticle is associated with a dimension equal to or less than 5 nm. For example, the method is implemented according to the method 100 and/or the method 300.

According to yet another embodiment of the present invention, a method for making nanoparticles with emission characteristics includes synthesizing a nanoparticle core including silicon and passivating a nanoparticle surface by at least nitrogen. The nanoparticle core and the nanoparticle surface each are a part of a nanoparticle, and the nanoparticle is associated with a dimension equal to or less than 20 nm. For example, the method is implemented according to the method 100 and/or the method 300.

According to yet another embodiment of the present invention, a method for making a nanoparticle with emission characteristics includes synthesizing a nanoparticle core including silicon and passivating a nanoparticle surface by at least one selected from a group consisting of carbon and germanium. The nanoparticle core and the nanoparticle surface each are a part of a nanoparticle, and the nanoparticle is associated with a dimension equal to or less than 20 nm. For example, the method is implemented according to the method 100 and/or the method 300.

According to yet another embodiment of the present invention, a method for making a nanoparticle with emission characteristics includes synthesizing a nanoparticle core including germanium and passivating a nanoparticle surface by at least silicon. The nanoparticle core and the nanoparticle surface each are a part of a nanoparticle, and the nanoparticle is associated with a dimension equal to or less than 20 nm. For example, the method is implemented according to the method 100 and/or the method 300.

According to yet another embodiment of the present invention, a method for making nanoparticles with emission characteristics includes synthesizing a nanoparticle core including a core material and forming a nanoparticle shell including a shell material and surrounding the nanoparticle core. The core material and the shell material are different, and the nanoparticle core and the nanoparticle shell each are a part of a nanoparticle. The nanoparticle is associated with a dimension equal to or less than 5 nm. For example, the method is implemented according to the method 100 and/or the method 300.

According to yet another embodiment of the present invention, a method for making nanoparticles with emission characteristics includes synthesizing a nanoparticle core including silicon and forming a nanoparticle shell surrounding the nanoparticle core. The nanoparticle core and the nanoparticle shell each are a part of a nanoparticle, the nanoparticle shell includes nitrogen, and the nanoparticle is associated with a dimension equal to or less than 20 nm. For example, the method is implemented according to the method 100 and/or the method 300.

According to yet another embodiment of the present invention, a method for making nanoparticles with emission characteristics includes synthesizing a nanoparticle core including silicon and forming a nanoparticle shell surrounding the nanoparticle core. The nanoparticle core and the nanoparticle shell each are a part of a nanoparticle, the nanoparticle shell includes at least one selected from a group consisting of carbon and germanium, and the nanoparticle is associated with a dimension equal to or less than 20 nm. For example, the method is implemented according to the method 100 and/or the method 300.

According to yet another embodiment of the present invention, a method for making nanoparticles with emission characteristics includes synthesizing a nanoparticle core including germanium and forming a nanoparticle shell surrounding the nanoparticle core. The nanoparticle core and the nanoparticle shell each are a part of a nanoparticle, the nanoparticle shell includes silicon, and the nanoparticle is associated with a dimension equal to or less than 20 nm. For example, the method is implemented according to the method 100 and/or the method 300.

According to yet another embodiment of the present invention, a method for making nanoparticles with emission characteristics includes providing a plasma microreactor. The plasma microreactor includes a cathode associated with a first end and a second end, an anode associated with a third end and a fourth end, and a container including a gas inlet. The first end and the third end are separated by a gap and located inside the container. Additionally, the method includes supplying a first gas flowing from the second end to the first end, supplying a second gas flowing from the gas inlet into the anode through at least a part of the gap, and starting and maintaining a plasma discharge at a pressure equal to or higher than one atmospheric pressure. The first gas is used at least for synthesizing a nanoparticle core, and the second gas is used at least for passivating a nanoparticle surface surrounding the nanoparticle core. The nanoparticle core and the nanoparticle surface are each a part of a nanoparticle, and the nanoparticle is associated with a dimension equal to or less than 20 nm. For example, the method is implemented according to the method 100 and/or the method 300.

According to yet another embodiment of the present invention, a method for making nanoparticles with emission characteristics includes providing a plasma microreactor. The plasma microreactor includes a cathode associated with a first end and a second end, an anode associated with a third end and a fourth end, and a container including a gas inlet. The first end and the third end are separated by a gap and located inside the container. Additionally, the method includes supplying a first gas flowing from the second end to the first end, supplying a second gas flowing from the gas inlet into the anode through at least a part of the gap, and starting and maintaining a plasma discharge at a pressure equal to or higher than one atmospheric pressure. The first gas is used at least for synthesizing a nanoparticle core, and the second gas is used at least for forming a nanoparticle shell surrounding the nanoparticle core. The nanoparticle core and the nanoparticle shell each are a part of the nanoparticle, and the nanoparticle is associated with a dimension equal to or less than 20 nm. For example, the method is implemented according to the method 100 and/or the method 300.

According to yet another embodiment of the present invention, a system for making nanoparticles with emission characteristics includes a first cathode including a first metal tube associated with a first end and a second end, a first anode including a second metal tube associated with a third end and a fourth end, and a first container including a first gas inlet. The first end and the third end are located inside the first container. Additionally, the system includes a first furnace coupled to the fourth end associated with the first anode. The first end and the third end are separated by a first gap. The first metal tube is configured to allow a first gas to flow from the second end to the first end, and the first container is configured to allow a second gas to flow from the first gas inlet into the second metal tube through at least a part of the first gap. The first cathode and the first anode are configured to generate a first plasma discharge at a first pressure equal to or higher than one atmospheric pressure. The first plasma discharge is capable of being used for synthesizing at least a first nanoparticle core, and the first furnace is configured to passivate a first nanoparticle surface surrounding the first nanoparticle core. The first nanoparticle core and the first nanoparticle surface are each a part of a first nanoparticle, and the first nanoparticle is associated with a dimension equal to or less than 20 nm. Additionally, the system, for example, includes a second cathode including a third metal tube associated with a fifth end and a sixth end, a second anode including a fourth metal tube associated with a seventh end and an eighth end, and a second furnace coupled to the eighth end associated with the second anode. The fifth end and the seventh end are separated by a second gap. The third metal tube is configured to allow a third gas to flow from the sixth end to the fifth end, and the second cathode and the second anode are configured to generate a second plasma discharge at a second pressure equal to or higher than one atmospheric pressure. The second plasma discharge is capable of being used for making a second nanoparticle core, and the second furnace is configured to passivate a second nanoparticle surface surrounding the second nanoparticle core. The second nanoparticle core and the second nanoparticle surface are each a part of a second nanoparticle, and the second nanoparticle is associated with a dimension equal to or less than 20 nm. For example, the system is implemented according to the system 200.

According to yet another embodiment of the present invention, a system for making nanoparticles with emission characteristics includes a first cathode including a first metal tube associated with a first end and a second end, a first anode including a second metal tube associated with a third end and a fourth end, and a first container including a first gas inlet. The first end and the third end are located inside the first container. Additionally, the system includes a first furnace coupled to the fourth end associated with the first anode. The first end and the third end are separated by a first gap. The first metal tube is configured to allow a first gas to flow from the second end to the first end, and the first container is configured to allow a second gas to flow from the first gas inlet into the second metal tube through at least a part of the first gap. The first cathode and the first anode are configured to generate a first plasma discharge at a first pressure equal to or higher than one atmospheric pressure; The first plasma discharge is capable of being used for synthesizing at least a first nanoparticle core, and the first furnace is configured to passivate a first nanoparticle shell surrounding the first nanoparticle core. The first nanoparticle core and the first nanoparticle shell each are a part of a first nanoparticle, and the first nanoparticle is associated with a dimension equal to or less than 20 nm. Additionally, the system, for example, includes a second cathode including a third metal tube associated with a fifth end and a sixth end, a second anode including a fourth metal tube associated with a seventh end and an eighth end, and a second furnace coupled to the eighth end associated with the second anode. The fifth end and the seventh end are separated by a second gap. The third metal tube is configured to allow a third gas to flow from the sixth end to the fifth end, and the second cathode and the second anode are configured to generate a second plasma discharge at a second pressure equal to or higher than one atmospheric pressure. The second plasma discharge is capable of being used for making a second nanoparticle core, and the second furnace is configured to passivate a second nanoparticle shell surrounding the second core. The second nanoparticle core and the second nanoparticle shell each are a part of a second nanoparticle, and the second nanoparticle is associated with a dimension equal to or less than 20 nm. For example, the system is implemented according to the system 200.

According to yet another embodiment of the present invention, a nanoparticle for emitting or absorbing light includes a nanoparticle core including silicon and a nanoparticle surface passivated by at least oxygen. The nanoparticle is associated with a dimension equal to or less than 5 nm. For example, the nanoparticle is made according to the method 100 and/or the method 300 with the system 200.

According to yet another embodiment of the present invention, a nanoparticle for emitting or absorbing light includes a nanoparticle core including silicon and a nanoparticle shell surrounding the nanoparticle core. The nanoparticle shell includes oxygen, and the nanoparticle is associated with a dimension equal to or less than 5 nm. For example, the nanoparticle is made according to the method 100 and/or the method 300 with the system 200.

According to yet another embodiment of the present invention, a method for making nanoparticles with emission characteristics includes synthesizing a nanoparticle core including silicon and passivating a nanoparticle surface by at least oxygen. The nanoparticle core and the nanoparticle surface each are a part of a nanoparticle, and the nanoparticle is associated with a dimension equal to or less than 5 nm. For example, the method is implemented according to the method 100 and/or the method 300.

According to yet another embodiment of the present invention, a method for making nanoparticles with emission characteristics includes synthesizing a nanoparticle core including silicon and forming a nanoparticle shell surrounding the nanoparticle core. The nanoparticle core and the nanoparticle shell each are a part of a nanoparticle, and the nanoparticle shell includes oxygen. The nanoparticle is associated with a dimension equal to or less than 5 nm. For example, the method is implemented according to the method 100 and/or the method 300.

The present invention has various advantages. Some embodiments of the present invention provide high-pressure microdischarges for the synthesis of nanometer-size particles with controlled emission properties. For example, the emission properties of the silicon nanoparticles are tailored to range from 350 to 700 nm. Certain embodiments of the present invention modify surface characteristics of nanoparticles. Some embodiments of the present invention can be applied to imaging and/or energy conversion. Certain embodiments of the present invention can be used for solar cells, LEDs, photodiodes, diode lasers, and/or memory systems.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

1. A nanoparticle for emitting or absorbing light, the nanoparticle comprising:
a nanoparticle core including a core material;
a nanoparticle surface passivated by at least a passivating material;
wherein:
the core material and the passivating material are different;
the nanoparticle is associated with a dimension equal to or less than 5 nm.

2. The nanoparticle of claim 1 wherein the nanoparticle is capable of emitting light, absorbing light, or both emitting light and absorbing light.

3. The nanoparticle of claim 1 wherein the dimension is a diameter.

4. The nanoparticle of claim 3 wherein the diameter is equal to or less than 3 nm.

5. The nanoparticle of claim 1 wherein the core material comprises a semiconductor material.

6. The nanoparticle of claim 5 wherein the semiconductor material comprises silicon.

7. The nanoparticle of claim 5 wherein the semiconductor material comprises germanium.

8. The nanoparticle of claim 1 wherein the core material comprises a metal material.

9. The nanoparticle of claim 8 wherein the metal material comprises at least one selected from a group consisting of iron, cobalt, and nickel.

10. The nanoparticle of claim 1 wherein the core material comprises a magnetic material.

11. The nanoparticle of claim 1 wherein the passivating material comprises nitrogen.

12. The nanoparticle of claim 1 wherein the passivating material comprises oxygen.

13. The nanoparticle of claim 1 wherein the passivating material comprises carbon.

14. The nanoparticle of claim 1 wherein the passivating material comprises germanium.

15. The nanoparticle of claim 1 wherein the passivating material comprises silicon.

16. A nanoparticle for emitting or absorbing light, the nanoparticle comprising:
a nanoparticle core including silicon;
a nanoparticle surface passivated by at least oxygen;
wherein the nanoparticle is associated with a dimension equal to or less than 5 nm.

17. The nanoparticle of claim 16 wherein the nanoparticle is capable of emitting light, absorbing light, or both emitting light and absorbing light.

18. The nanoparticle of claim 16 wherein the dimension is a diameter.

19. The nanoparticle of claim 18 wherein the diameter is equal to or less than 3 nm.

20. A nanoparticle for emitting or absorbing light, the nanoparticle comprising:
a nanoparticle core including silicon;
a nanoparticle surface passivated by at least nitrogen;
wherein the nanoparticle is associated with a dimension equal to or less than 20 nm.

21. The nanoparticle of claim 20 wherein the nanoparticle is capable of emitting light, absorbing light, or both emitting light and absorbing light.

22. The nanoparticle of claim 20 wherein the dimension is a diameter.

23. The nanoparticle of claim 22 wherein the diameter is equal to or less than 5 nm.

24. The nanoparticle of claim 23 wherein the diameter is equal to or less than 3 nm.

25. A nanoparticle for emitting or absorbing light, the nanoparticle comprising:
a nanoparticle core including silicon;
a nanoparticle surface passivated by at least one selected from a group consisting of carbon and germanium;
wherein the nanoparticle is associated with a dimension equal to or less than 20 nm.

26. The nanoparticle of claim 25 wherein the nanoparticle is capable of emitting light, absorbing light, or both emitting light and absorbing light.

27. The nanoparticle of claim 25 wherein the dimension is a diameter.

28. The nanoparticle of claim 27 wherein the diameter is equal to or less than 5 nm.

29. The nanoparticle of claim 28 wherein the diameter is equal to or less than 3 nm.

30. A nanoparticle for emitting or absorbing light, the nanoparticle comprising:
a nanoparticle core including germanium;
a nanoparticle surface passivated by at least silicon;
wherein the nanoparticle is associated with a dimension equal to or less than 20 nm.

31. The nanoparticle of claim 30 wherein the nanoparticle is capable of emitting light, absorbing light, or both emitting light and absorbing light.

32. The nanoparticle of claim 30 wherein the dimension is a diameter.

33. The nanoparticle of claim 32 wherein the diameter is equal to or less than 5 nm.

34. The nanoparticle of claim 33 wherein the diameter is equal to or less than 3 nm.

35. A nanoparticle for emitting or absorbing light, the nanoparticle comprising:
a nanoparticle core including silicon;
a nanoparticle surface passivated by at least a metal material;
wherein the nanoparticle is associated with a dimension equal to or less than 20 nm.

36. The nanoparticle of claim 35 wherein the nanoparticle is capable of emitting light, absorbing light, or both emitting light and absorbing light.

37. The nanoparticle of claim 35 wherein the dimension is a diameter.

38. The nanoparticle of claim 37 wherein the diameter is equal to or less than 5 nm.

39. The nanoparticle of claim 38 wherein the diameter is equal to or less than 3 nm.

40. The nanoparticle of claim 35 wherein the metal material comprises at least one selected from a group consisting of iron, nickel, and cobalt.

41. A nanoparticle for emitting or absorbing light, the nanoparticle comprising:
a nanoparticle core including silicon;
a nanoparticle surface passivated by at least a magnetic material;
wherein the nanoparticle is associated with a dimension equal to or less than 20 nm.

42. The nanoparticle of claim 41 wherein the nanoparticle is capable of emitting light, absorbing light, or both emitting light and absorbing light.

43. The nanoparticle of claim 41 wherein the dimension is a diameter.

44. The nanoparticle of claim 43 wherein the diameter is equal to or less than 5 nm.

45. The nanoparticle of claim 44 wherein the diameter is equal to or less than 3 nm.

46. A nanoparticle for emitting or absorbing light, the nanoparticle comprising:
a nanoparticle core including a core material;
a nanoparticle shell including a shell material and surrounding the nanoparticle core;
wherein
the core material and the shell material are different;
the nanoparticle is associated with a dimension equal to or less than 5 nm.

47. The nanoparticle of claim 46 wherein the nanoparticle is capable of emitting light, absorbing light, or both emitting light and absorbing light.

48. The nanoparticle of claim 46 wherein the dimension is a diameter.

49. The nanoparticle of claim 48 wherein the diameter is equal to or less than 3 nm.

50. The nanoparticle of claim 46 wherein the core material comprises a semiconductor material.

51. The nanoparticle of claim 50 wherein the semiconductor material comprises silicon.

52. The nanoparticle of claim 50 wherein the semiconductor material comprises germanium.

53. The nanoparticle of claim 46 wherein the core material comprises a metal material.

54. The nanoparticle of claim 53 wherein the metal material comprises at least one selected from a group consisting of iron, cobalt, and nickel.

55. The nanoparticle of claim 46 wherein the core material comprises a magnetic material.

56. The nanoparticle of claim 46 wherein the shell material comprises nitrogen.

57. The nanoparticle of claim 46 wherein the shell material comprises oxygen.

58. The nanoparticle of claim 46 wherein the shell material comprises carbon.

59. The nanoparticle of claim 46 wherein the shell material comprises germanium.

60. The nanoparticle of claim 46 wherein the shell material comprises silicon.

61. The nanoparticle of claim 46 wherein the shell material comprises a metal material.

62. The nanoparticle of claim 61 wherein the metal material comprises at least one selected from a group consisting of iron, cobalt, and nickel.

63. A nanoparticle for emitting or absorbing light, the nanoparticle comprising:
a nanoparticle core including silicon;
a nanoparticle shell surrounding the nanoparticle core;
wherein:
the nanoparticle shell includes oxygen;
the nanoparticle is associated with a dimension equal to or less than 5 nm.

64. The nanoparticle of claim 63 wherein the nanoparticle is capable of emitting light, absorbing light, or both emitting light and absorbing light.

65. The nanoparticle of claim 63 wherein the dimension is a diameter.

66. The nanoparticle of claim 65 wherein the diameter is equal to or less than 3 nm.

67. A nanoparticle for emitting or absorbing light, the nanoparticle comprising:
a nanoparticle core including silicon;
a nanoparticle shell surrounding the nanoparticle core;
wherein:
the nanoparticle shell includes nitrogen;
the nanoparticle is associated with a dimension equal to or less than 20 nm.

68. The nanoparticle of claim 67 wherein the nanoparticle is capable of emitting light, absorbing light, or both emitting light and absorbing light.

69. The nanoparticle of claim 67 wherein the dimension is a diameter.

70. The nanoparticle of claim 69 wherein the diameter is equal to or less than 5 nm.

71. The nanoparticle of claim 70 wherein the diameter is equal to or less than 3 nm.

72. A nanoparticle for emitting or absorbing light, the nanoparticle comprising:
a nanoparticle core including silicon;
a nanoparticle shell surrounding the nanoparticle core;
wherein:
the nanoparticle shell includes at least one selected from a group consisting of carbon and germanium;
the nanoparticle is associated with a dimension equal to or less than 20 nm.

73. The nanoparticle of claim 72 wherein the nanoparticle is capable of emitting light, absorbing light, or both emitting light and absorbing light.

74. The nanoparticle of claim 72 wherein the dimension is a diameter.

75. The nanoparticle of claim 74 wherein the diameter is equal to or less than 5 nm.

76. The nanoparticle of claim 75 wherein the diameter is equal to or less than 3 nm.

77. A nanoparticle for emitting or absorbing light, the nanoparticle comprising:
a nanoparticle core including germanium;
a nanoparticle shell surrounding the nanoparticle core;
wherein:
the nanoparticle shell includes silicon;
the nanoparticle is associated with a dimension equal to or less than 20 nm.

78. The nanoparticle of claim 77 wherein the nanoparticle is capable of emitting light, absorbing light, or both emitting light and absorbing light.

79. The nanoparticle of claim 77 wherein the dimension is a diameter.

80. The nanoparticle of claim 79 wherein the diameter is equal to or less than 5 nm.

81. The nanoparticle of claim 80 wherein the diameter is equal to or less than 3 nm.

82. A nanoparticle for emitting or absorbing light, the nanoparticle comprising:
a nanoparticle core including silicon;
a nanoparticle shell surrounding the nanoparticle core;
wherein:
the nanoparticle shell includes a metal material;
the nanoparticle is associated with a dimension equal to or less than 20 nm.

83. The nanoparticle of claim 82 wherein the nanoparticle is capable of emitting light, absorbing light, or both emitting light and absorbing light.

84. The nanoparticle of claim 82 wherein the dimension is a diameter.

85. The nanoparticle of claim 84 wherein the diameter is equal to or less than 5 nm.

86. The nanoparticle of claim 85 wherein the diameter is equal to or less than 3 nm.

87. The nanoparticle of claim 82 wherein the metal material comprises at least one selected from a group consisting of iron, nickel, and cobalt.

88. A nanoparticle for emitting or absorbing light, the nanoparticle comprising:
a nanoparticle core including silicon;
a nanoparticle shell surrounding the nanoparticle core;
wherein:
the nanoparticle shell includes a magnetic material;
the nanoparticle is associated with a dimension equal to or less than 20 nm.

89. The nanoparticle of claim 88 wherein the nanoparticle is capable of emitting light, absorbing light, or both emitting light and absorbing light.

90. The nanoparticle of claim 88 wherein the dimension is a diameter.

91. The nanoparticle of claim 90 wherein the diameter is equal to or less than 5 nm.

92. The nanoparticle of claim 91 wherein the diameter is equal to or less than 3 nm.

93. A method for making nanoparticles with emission characteristics, the method comprising:
synthesizing a nanoparticle core including a core material;
passivating a nanoparticle surface by at least a passivating material;
wherein:
the core material and the passivating material are different
the nanoparticle core and the nanoparticle surface each are a part of a nanoparticle;
the nanoparticle is associated with a dimension equal to or less than 5 nm.

94. The method of claim 93 wherein the nanoparticle is capable of emitting light, absorbing light, or both emitting light and absorbing light.

95. The method of claim 93 wherein the synthesizing a nanoparticle core and the passivating a nanoparticle surface are performed sequentially.

96. The method of claim 93 wherein the synthesizing a nanoparticle core and the passivating a nanoparticle surface at least partially overlap in time.

97. The method of claim 93 wherein the dimension is a diameter.

98. The method of claim 97 wherein the diameter is equal to or less than 3 nm.

99. The method of claim 93 wherein the core material comprises a semiconductor material.

100. The method of claim 99 wherein the semiconductor material comprises silicon.

101. The method of claim 99 wherein the semiconductor material comprises germanium.

102. The method of claim 93 wherein the core material comprises a metal material.

103. The method of claim 102 wherein the metal material comprises at least one selected from a group consisting of iron, cobalt, and nickel.

104. The method of claim 93 wherein the core material comprises a magnetic material.

105. The method of claim 93 wherein the passivating material comprises nitrogen.

106. The method of claim 93 wherein the passivating material comprises oxygen.

107. The method of claim 93 wherein the passivating material comprises carbon.

108. The method of claim 93 wherein the passivating material comprises germanium.

109. The method of claim 93 wherein the passivating material comprises silicon.

110. A method for making nanoparticles with emission characteristics, the method comprising:
synthesizing a nanoparticle core including silicon;
passivating a nanoparticle surface by at least oxygen;
wherein:
the nanoparticle core and the nanoparticle surface each are a part of a nanoparticle;
the nanoparticle is associated with a dimension equal to or less than 5 nm.

111. The method of claim 110 wherein the nanoparticle is capable of emitting light, absorbing light, or both emitting light and absorbing light.

112. The method of claim 110 wherein the dimension is a diameter.

113. The method of claim 112 wherein the diameter is equal to or less than 3 nm.

114. A method for making nanoparticles with emission characteristics, the method comprising:
synthesizing a nanoparticle core including silicon;
passivating a nanoparticle surface by at least nitrogen;
wherein:
the nanoparticle core and the nanoparticle surface each are a part of a nanoparticle;
the nanoparticle is associated with a dimension equal to or less than 20 nm.

115. The method of claim 114 wherein the nanoparticle is capable of emitting light, absorbing light, or both emitting light and absorbing light.

116. The method of claim 114 wherein the dimension is a diameter.

117. The method of claim 116 wherein the diameter is equal to or less than 5 nm.

118. The method of claim 117 wherein the diameter is equal to or less than 3 nm.

119. A method for making a nanoparticle with emission characteristics, the method comprising:
synthesizing a nanoparticle core including silicon;
passivating a nanoparticle surface by at least one selected from a group consisting of carbon and germanium;
wherein:
the nanoparticle core and the nanoparticle surface each are a part of a nanoparticle;
the nanoparticle is associated with a dimension equal to or less than 20 nm.

120. The method of claim 119 wherein the nanoparticle is capable of emitting light, absorbing light, or both emitting light and absorbing light.

121. A method for making a nanoparticle with emission characteristics, the method comprising:
synthesizing a nanoparticle core including germanium;
passivating a nanoparticle surface by at least silicon;
wherein:
the nanoparticle core and the nanoparticle surface each are a part of a nanoparticle;
the nanoparticle is associated with a dimension equal to or less than 20 nm.

122. The method of claim 121 wherein the nanoparticle is capable of emitting light, absorbing light, or both emitting light and absorbing light.

123. A method for making nanoparticles with emission characteristics, the method comprising:
synthesizing a nanoparticle core including a core material;
forming a nanoparticle shell including a shell material and surrounding the nanoparticle core;
wherein:
the core material and the shell material are different;
the nanoparticle core and the nanoparticle shell each are a part of a nanoparticle;
the nanoparticle is associated with a dimension equal to or less than 5 nm.

124. The method of claim 123 wherein the nanoparticle is capable of emitting light, absorbing light, or both emitting light and absorbing light.

125. The method of claim 123 wherein the dimension is a diameter.

126. The method of claim 125 wherein the diameter is equal to or less than 3 nm.

127. The method of claim 123 wherein the core material comprises a semiconductor material.

128. The method of claim 127 wherein the semiconductor material comprises silicon.

129. The method of claim 127 wherein the semiconductor material comprises germanium.

130. The method of claim 123 wherein the core material comprises a metal material.

131. The method of claim 130 wherein the metal material comprises at least one selected from a group consisting of iron, cobalt, and nickel.

132. The method of claim 123 wherein the core material comprises a magnetic material.

133. The method of claim 123 wherein the shell material comprises nitrogen.

134. The method of claim 123 wherein the shell material comprises oxygen.

135. The method of claim 123 wherein the shell material comprises carbon.

136. The method of claim 123 wherein the shell material comprises germanium.

137. The method of claim 123 wherein the shell material comprises silicon.

138. The method of claim 123 wherein the shell material comprises a metal material.

139. The method of claim 138 wherein the metal material comprises at least one selected from a group consisting of iron, cobalt, and nickel.

140. A method for making nanoparticles with emission characteristics, the method comprising:
synthesizing a nanoparticle core including silicon;
forming a nanoparticle shell surrounding the nanoparticle core;
wherein:
the nanoparticle core and the nanoparticle shell each are a part of a nanoparticle;
the nanoparticle shell includes oxygen;
the nanoparticle is associated with a dimension equal to or less than 5 nm.

141. The method of claim 140 wherein the nanoparticle is capable of emitting light, absorbing light, or both emitting light and absorbing light.

142. The method of claim 140 wherein the dimension is a diameter.

143. The method of claim 142 wherein the diameter is equal to or less than 3 nm.

144. A method for making nanoparticles with emission characteristics, the method comprising:
synthesizing a nanoparticle core including silicon;
forming a nanoparticle shell surrounding the nanoparticle core;
wherein:
the nanoparticle core and the nanoparticle shell each are a part of a nanoparticle;
the nanoparticle shell includes nitrogen;
the nanoparticle is associated with a dimension equal to or less than 20 nm.

145. The method of claim 144 wherein the nanoparticle is capable of emitting light, absorbing light, or both emitting light and absorbing light.

146. The method of claim 144 wherein the dimension is a diameter.

147. The method of claim 146 wherein the diameter is equal to or less than 5 nm.

148. The method of claim 147 wherein the diameter is equal to or less than 3 nm.

149. A method for making nanoparticles with emission characteristics, the method comprising:
synthesizing a nanoparticle core including silicon;
forming a nanoparticle shell surrounding the nanoparticle core;
wherein:
the nanoparticle core and the nanoparticle shell each are a part of a nanoparticle;
the nanoparticle shell includes at least one selected from a group consisting of carbon and germanium;
the nanoparticle is associated with a dimension equal to or less than 20 nm.

150. The method of claim 149 wherein the nanoparticle is capable of emitting light, absorbing light, or both emitting light and absorbing light.

151. A method for making nanoparticles with emission characteristics, the method comprising:
synthesizing a nanoparticle core including germanium;
forming a nanoparticle shell surrounding the nanoparticle core;
wherein:
the nanoparticle core and the nanoparticle shell each are a part of a nanoparticle;
the nanoparticle shell includes silicon;
the nanoparticle is associated with a dimension equal to or less than 20 nm.

152. The method of claim 151 wherein the nanoparticle is capable of emitting light, absorbing light, or both emitting light and absorbing light.

153. A method for making nanoparticles with emission characteristics, the method comprising:
providing a plasma microreactor, the plasma microreactor including a cathode associated with a first end and a second end, an anode associated with a third end and a fourth end, and a container including a gas inlet, the first end and the third end being separated by a gap and located inside the container;
supplying a first gas flowing from the second end to the first end;
supplying a second gas flowing from the gas inlet into the anode through at least a part of the gap;
starting and maintaining a plasma discharge at a pressure equal to or higher than one atmospheric pressure;
wherein:
the first gas is used at least for synthesizing a nanoparticle core;
the second gas is used at least for passivating a nanoparticle surface surrounding the nanoparticle core;
the nanoparticle core and the nanoparticle surface are each a part of a nanoparticle;
the nanoparticle is associated with a dimension equal to or less than 20 nm.

154. The method of claim 153 wherein the nanoparticle is capable of emitting light, absorbing light, or both emitting light and absorbing light.

155. The method of claim 153 wherein the first gas comprises a precursor.

156. The method of claim 155 wherein the first gas further comprises an inert gas.

157. The method of claim 156 wherein:
the precursor includes silane;
the inert gas includes argon.

158. The method of claim 153 wherein the second gas comprises nitrogen.

159. The method of claim 153 wherein the second gas comprises oxygen.

160. The method of claim 159 wherein the second gas further comprises argon.

161. The method of claim 160 wherein the second gas comprises a percentage of oxygen, the percentage being equal to or lower than 1%.

162. The method of claim 153, and further comprising collecting at least the nanoparticle.

163. The method of claim 162 wherein the collecting at least the nanoparticle comprises collecting at least the nanoparticle in a liquid.

164. The method of claim 162 wherein the collecting at least the nanoparticle comprises collecting at least the nanoparticle on a substrate.

165. The method of claim 153, and further comprising analyzing at least the nanoparticle.

166. The method of claim 153 wherein the dimension is a diameter.

167. The method of claim 166 wherein the dimension is equal to or less than 5 nm.

168. The method of claim 167 wherein the dimension is equal to or less than 3 nm.

169. A method for making nanoparticles with emission characteristics, the method comprising:
providing a plasma microreactor, the plasma microreactor including a cathode associated with a first end and a second end, an anode associated with a third end and a fourth end, and a container including a gas inlet, the first end and the third end being separated by a gap and located inside the container;
supplying a first gas flowing from the second end to the first end;
supplying a second gas flowing from the gas inlet into the anode through at least a part of the gap;
starting and maintaining a plasma discharge at a pressure equal to or higher than one atmospheric pressure;
wherein:
the first gas is used at least for synthesizing a nanoparticle core;
the second gas is used at least for forming a nanoparticle shell surrounding the nanoparticle core;
the nanoparticle core and the nanoparticle shell each are a part of the nanoparticle;
the nanoparticle is associated with a dimension equal to or less than 20 nm.

170. The method of claim 169 wherein the nanoparticle is capable of emitting light, absorbing light, or both emitting light and absorbing light.

171. The method of claim 169 wherein the first gas comprises a precursor.

172. The method of claim 171 wherein the first gas further comprises an inert gas.

173. The method of claim 172 wherein:
the precursor includes silane;
the inert gas includes argon.

174. The method of claim 169 wherein the second gas comprises nitrogen.

175. The method of claim 169 wherein the second gas comprises oxygen.

176. The method of claim 175 wherein the second gas further comprises argon.

177. The method of claim 176 wherein the second gas comprises a percentage of oxygen, the percentage being equal to or lower than 1%.

178. The method of claim 169, and further comprising collecting at least the nanoparticle.

179. The method of claim 178 wherein the collecting at least the nanoparticle comprises collecting at least the nanoparticle in a liquid.

180. The method of claim 178 wherein the collecting at least the nanoparticle comprises collecting at least the nanoparticle on a substrate.

181. The method of claim 169, and further comprising analyzing at least the nanoparticle.

182. The method of claim 169 wherein the dimension is a diameter.

183. The method of claim 182 wherein the dimension is equal to or less than 5 nm.

184. The method of claim 183 wherein the dimension is equal to or less than 3 nm.

185. A system for making nanoparticles with emission characteristics, the system comprising:
a first cathode including a first metal tube associated with a first end and a second end;
a first anode including a second metal tube associated with a third end and a fourth end;
a first container including a first gas inlet, the first end and the third end being located inside the first container;
a first furnace coupled to the fourth end associated with the first anode;
wherein:
the first end and the third end are separated by a first gap;
the first metal tube is configured to allow a first gas to flow from the second end to the first end;
the first container is configured to allow a second gas to flow from the first gas inlet into the second metal tube through at least a part of the first gap;
the first cathode and the first anode are configured to generate a first plasma discharge at a first pressure equal to or higher than one atmospheric pressure;
the first plasma discharge is capable of being used for synthesizing at least a first nanoparticle core;
the first furnace is configured to passivate a first nanoparticle surface surrounding the first nanoparticle core;
the first nanoparticle core and the first nanoparticle surface are each a part of a first nanoparticle;
the first nanoparticle is associated with a dimension equal to or less than 20 nm.

186. The system of claim 185 wherein the first nanoparticle is capable of emitting light, absorbing light, or both emitting light and absorbing light.

187. The system of claim 185 wherein the second gas comprises nitrogen.

188. The system of claim 185 wherein the second gas comprises oxygen.

189. The system of claim 188 wherein the second gas further comprises argon.

190. The system of claim 189 wherein the second gas comprises a percentage of oxygen, the percentage being equal to or lower than 1%.

191. The system of claim 185 wherein:
a first metal tube is associated with a first inner diameter;
a second metal tube is associated with a second inner diameter;
the second inner diameter is lager than the first inner diameter.

192. The system of claim 185 wherein:
the first metal tube is associated with a longitudinal direction from the first end and the second end;
with respect to the longitudinal direction, the gas inlet is located between the first end and the second end.

193. The system of claim 185, and further comprising a particle collector coupled to the second metal tube.

194. The system of claim 193 wherein the particle collector comprise a liquid.

195. The system of claim 193 wherein the particle collector comprises a substrate.

196. The system of claim 185, and further comprising a size classifier coupled to the second metal tube.

197. The system of claim 196, and further comprising an electrometer coupled to the size classifier.

198. The system of claim 185, and further comprising:
a second cathode including a third metal tube associated with a fifth end and a sixth end;
a second anode including a fourth metal tube associated with a seventh end and an eighth end;
a second furnace coupled to the eighth end associated with the second anode;
wherein:
the fifth end and the seventh end are separated by a second gap;
the third metal tube is configured to allow a third gas to flow from the sixth end to the fifth end;
the second cathode and the second anode are configured to generate a second plasma discharge at a second pressure equal to or higher than one atmospheric pressure;
the second plasma discharge is capable of being used for making a second nanoparticle core;
the second furnace is configured to passivate a second nanoparticle surface surrounding the second nanoparticle core;
the second nanoparticle core and the second nanoparticle surface are each a part of a second nanoparticle;
the second nanoparticle is associated with a dimension equal to or less than 20 nm.

199. A system for making nanoparticles with emission characteristics, the system comprising:
a first cathode including a first metal tube associated with a first end and a second end;
a first anode including a second metal tube associated with a third end and a fourth end;
a first container including a first gas inlet, the first end and the third end being located inside the first container;
a first furnace coupled to the fourth end associated with the first anode;
wherein:
the first end and the third end are separated by a first gap;
the first metal tube is configured to allow a first gas to flow from the second end to the first end;
the first container is configured to allow a second gas to flow from the first gas inlet into the second metal tube through at least a part of the first gap;
the first cathode and the first anode are configured to generate a first plasma discharge at a first pressure equal to or higher than one atmospheric pressure;
the first plasma discharge is capable of being used for synthesizing at least a first nanoparticle core;
the first furnace is configured to passivate a first nanoparticle shell surrounding the first nanoparticle core;
the first nanoparticle core and the first nanoparticle shell each are a part of a first nanoparticle;
the first nanoparticle is associated with a dimension equal to or less than 20 nm.

200. The system of claim 199 wherein the first nanoparticle is capable of emitting light, absorbing light, or both emitting light and absorbing light.

201. The method of claim 199 wherein the second gas comprises nitrogen.

202. The method of claim 199 wherein the second gas comprises oxygen.

203. The method of claim 202 wherein the second gas further comprises argon.

204. The method of claim 203 wherein the second gas comprises a percentage of oxygen, the percentage being equal to or lower than 1%.

205. The system of claim 199 wherein:
a first metal tube is associated with a first inner diameter;
a second metal tube is associated with a second inner diameter;
the second inner diameter is lager than the first inner diameter.

206. The system of claim 199 wherein:
the first metal tube is associated with a longitudinal direction from the first end and the second end;
with respect to the longitudinal direction, the gas inlet is located between the first end and the second end.

207. The system of claim 199, and further comprising a particle collector coupled to the second metal tube.

208. The system of claim 207 wherein the particle collector comprise a liquid.

209. The system of claim 207 wherein the particle collector comprises a substrate.

210. The system of claim 199, and further comprising a size classifier coupled to the second metal tube.

211. The system of claim 210, and further comprising an electrometer coupled to the size classifier.

212. The system of claim 199, and further comprising:
a second cathode including a third metal tube associated with a fifth end and a sixth end;
a second anode including a fourth metal tube associated with a seventh end and an eighth end;
a second furnace coupled to the eighth end associated with the second anode;
wherein:
the fifth end and the seventh end are separated by a second gap;
the third metal tube is configured to allow a third gas to flow from the sixth end to the fifth end;
the second cathode and the second anode are configured to generate a second plasma discharge at a second pressure equal to or higher than one atmospheric pressure;
the second plasma discharge is capable of being used for making a second nanoparticle core;
the second furnace is configured to passivate a second nanoparticle shell surrounding the second core;
the second nanoparticle core and the second nanoparticle shell each are a part of a second nanoparticle;
the second nanoparticle is associated with a dimension equal to or less than 20 nm.
